(19) United States
(12) Patent Application Publication
(10) Pub. No.: US 2015/0062478 A1
(43) Pub. Date: Mar. 5, 2015

(54) TFT ARRAY SUBSTRATE, DISPLAY PANEL AND DISPLAY DEVICE

(71) Applicants: Tianma Micro-Electronics Co., Ltd., Shenzhen (CN); Shanghai Tianma Micro-Electronics Co., Ltd., Shanghai (CN)

(72) Inventors: Xuewen ZHAO, Shanghai (CN); Xiongping Li, Shanghai (CN); Zhonghua Wang, Shanghai (CN)

(73) Assignees: Tianma Micro-Electronics Co., Ltd., Shenzhen (CN); Shanghai Tianma Micro-Electronics Co., Ltd., Shanghai (CN)

(21) Appl. No.: 14/231,449

(22) Filed: Mar. 31, 2014

(30) Foreign Application Priority Data
Sep. 4, 2013 (CN) 201310398440.2

(51) Int. Cl. G02F 1/13; H01L 27/12

(52) U.S. Cl. CPC G02F 1/1309; H01L 27/124
USPC 349/54; 257/48

(57) ABSTRACT

Embodiments of the present invention disclose a TFT array substrate, a display panel and a display device. Gap directions of gaps formed between visual test pads in a visual test area on the TFT array substrate are staggered with the alignment direction of an alignment film on the same plane with at least one staggered angle, and the staggered angle is more than 5 degrees, so that the problem of Rubbing Mura is solved.

### CROSS-REFERENCES TO RELATED APPLICATIONS

This application claims the benefit of priority to Chinese Patent Application No. 201310398440.2, filed with the Chinese Patent Office on Sep. 4, 2013 and entitled “TFT ARRAY SUBSTRATE, DISPLAY PANEL AND DISPLAY DEVICE”, the content of which is incorporated herein by reference in its entirety.

### TECHNICAL FIELD

The present invention relates to the field of active matrix arrays, and particularly relates to a thin film transistor (TFT) array substrate including a visual test area, a display panel including the TFT array substrate and a display device.

### BACKGROUND OF THE INVENTION

A TFT-LCD (Thin Film Transistor-Liquid Crystal Display) displays images by using the intensity change of an electric field on a liquid crystal layer to change the orientation of liquid crystal molecules to control the intensity of transmitted light. Generally, a complete liquid crystal display panel must be composed of a backlight module, a polarizer, a TFT array substrate, a color filter (CF) substrate and a liquid crystal molecule layer filled in a cell formed by the two substrates. In the manufacturing process of the TFT-LCD, after the TFT array substrate is combined with the CF substrate to form a display module (Cell) and before an integrated circuit (IC) is welded to the Cell, a step of testing the function of each component on the TFT substrate, namely Cell Visual Test, is needed. The Cell Visual Test generally includes testing whether data lines, scan lines, common electrode lines, a TFT switch and the like on the TFT substrate can work normally. To implement the above-mentioned test, a visual test area is generally designed in the periphery of a display area on the TFT substrate and includes multiple visual test pads for detecting different components. Such design avoids the following conditions, namely when a component on the TFT substrate are not qualified, namely the yield of the components does not reach 100%, if one unqualified Cell with an irreparable component flows to next process flow, namely a module section, the IC is bound with the Cell in the module section. If adverse problems are discovered through pad detection after the IC is bound, the bound related components such as the IC and the like need to be detached; and after the components such as the IC and the like are detached, the detached components such as the IC, an FPC (flexible printed circuit board) and the like may be damaged due to the technical limitation of the prior art, thus materials such as the IC, the FPC and the like may be wasted. Accordingly, a detection process, namely the Cell Visual Test, is always set in the Cell section in a factory, to prevent adverse Cells in a certain ratio from flowing to next process to bring unnecessary loss.

FIG. 1 shows a schematic diagram of a structural design of a visual test area and visual test pads on a TFT substrate in the prior art. Wherein, the visual test area 2 (elliptical dotted box in FIG. 1) in the periphery area B of the display area A of the TFT substrate 1 includes multiple visual test pads 3. The geometrical shapes of the visual test pads 3 are generally rectangles, all the visual test pads 3 are equal in size, and the multiple visual test pads 3 are successively arranged on the same straight line. Because the visual test pads 3 are not arranged tightly, gaps 4 with relatively large area are formed. Because the visual test pads 3 are formed before an alignment film on the TFT substrate 1, when the alignment film is coated on the TFT substrate 1, namely a Rubbing process is performed, a lint roller sweeps the gaps 4 formed between the visual test pads 3; and because the direction H (dotted line in FIG. 1) of the gaps 4 is substantially consistent with the Rubbing direction R (dotted line in FIG. 1), lint on the lint roller has a deformation in accordance with the gap direction, thus the shape of fine grooves originally deployed in the lint is changed, the alignment direction in the part of the lint which swept the gaps 4 is different from alignment direction in other parts, Rubbing uniformity is affected to produce Rubbing Mura, and vertical stripe Mura is generally produced.

### BRIEF SUMMARY OF THE INVENTION

In view of this, embodiments of the present invention provide a TFT array substrate, a display panel and a display device.

According to an exemplary embodiment of the present invention, a TFT array substrate is provided and includes: a substrate, provided with a display area and a peripheral area of the display area; a visual test area, formed in the peripheral area and including at least two visual test pads between which at least one gap with a gap direction is formed; and an alignment film, formed in the display area and having an alignment direction; wherein, the gap direction is staggered with the alignment direction on the same plane with at least one staggered angle, and the staggered angle is more than 5 degrees.

According to an exemplary embodiment of the present invention, a display panel is provided and includes the above-mentioned TFT array substrate, a color filter substrate opposite to the TFT array substrate and a liquid crystal layer between the TFT array substrate and the color filter substrate.

According to an exemplary embodiment of the present invention, a display device is provided and includes the above-mentioned display panel.

As known from the above-mentioned technical solutions, compared with the prior art, embodiments of the present invention disclose the TFT array substrate, the display panel and the display device. The gaps are formed between the visual test pads in the visual test area on the TFT array substrate, the gap directions of the gaps are staggered with the alignment direction of the alignment film on the same plane with at least one staggered angle, and the staggered angle is more than 5 degrees, so that the problem of Rubbing Mura is solved.

### BRIEF DESCRIPTION OF THE DRAWINGS

To illustrate technical solutions in the embodiments of the present invention more clearly, a brief introduction on the accompanying drawings which are needed in the description of the embodiments is given below. Obviously, the accompanying drawings in the description below are merely some of the embodiments of the present invention, based on which other drawings may be obtained by those of ordinary skilled in the art without any creative effort.

FIG. 1 is a schematic diagram of a structural design of a visual test area and visual test pads on a TFT substrate in the prior art;

FIG. 2 is a schematic diagram of a structural design of a visual test area and visual test pads on a TFT substrate in an embodiment I;

FIG. 3 is a schematic diagram of a structural design of a visual test area and visual test pads on a TFT substrate in an embodiment II;

FIG. 4 is a schematic diagram of a structural design of a visual test area and visual test pads on a TFT substrate in an embodiment III;

FIG. 5 is a schematic diagram of a structural design of a visual test area and visual test pads on a TFT substrate in an embodiment IV;

FIG. 6 is a schematic diagram of a structural design of a visual test area and visual test pads on a TFT substrate in an embodiment V;

FIG. 7 is a schematic diagram of a structural design of a visual test area and visual test pads on a TFT substrate in an embodiment VI;

FIG. 8 is a schematic diagram of a structural design of a visual test area and visual test pads on a TFT substrate in an embodiment VII.

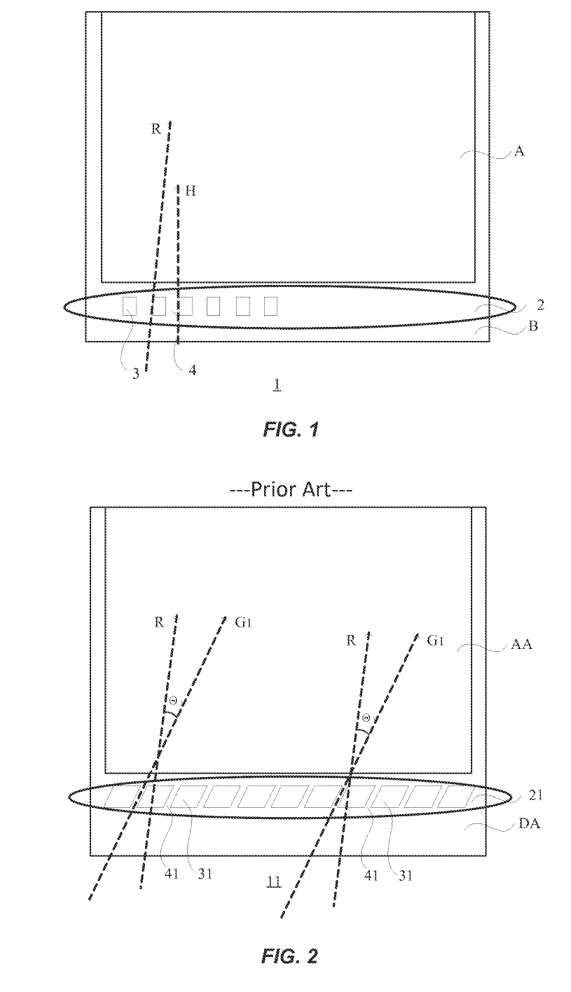

### DETAILED DESCRIPTION OF THE PREFERRED EMBODIMENTS

A clear and complete description of technical solutions in the embodiments of the present invention will be given below, in conjunction with the accompanying drawings in the embodiments of the present invention. Obviously, the embodiments described are merely a part, but not all, of the embodiments of the present invention. All of other embodiments, obtained by those of ordinary skilled in the art based on the embodiments of the present invention without any creative effort, fall into the protection scope of the present invention.

Embodiments of the present invention disclose a TFT array substrate, a display panel and a display device. Gap directions of gaps formed between visual test pads in a visual test area on the TFT array substrate are staggered with the alignment direction of an alignment film on the same plane with at least one staggered angle, and the staggered angle is more than 5 degrees, so that the problem of Rubbing Mura is solved.

The staggered angles of the gap directions and the alignment direction on the same plane in the present invention and the following embodiments refer to acute staggered angles produced when the gap directions and the alignment direction are staggered; the size of the staggered angles also refer to the size of the acute staggered angles, the staggered angles in the present invention are more than 5 degrees, and because the staggered angles are the acute staggered angles, the upper limit of the staggered angles is 90 degrees.

In addition, it should be noted that Data R pad, Data G pad, Data B pad, COM pad, Gate Odd pad, Gate Even pad, Switch pad, STV pad, CLK pad or CKB pad involved in the following embodiments are as follows.

The Data R pad is a pad for testing all source lines of red pixels of a CF substrate corresponding to the TFT substrate.

The Data G pad is a pad for testing all source lines of green pixels of the CF substrate corresponding to the TFT substrate.

The Data B pad is a pad for testing all source lines of blue pixels of the CF substrate corresponding to the TFT substrate.

The COM pad is a pad for testing all common electrodes on the TFT substrate.

The Gate Odd pad is a pad for testing all odd lines of gate lines on the TFT substrate.

The Gate Even pad is a pad for testing all even lines of gate lines on the TFT substrate.

The Switch pad is a pad for testing a TFT with a switch effect, since the Switch has a TFT structure with the switch effect. Generally, the Switch pad is not set in the visual test area of a large-sized TFT array substrate, but is set in a medium or small-sized TFT array substrate.

The STV pad is a pad for testing all test initial signal end leads on the TFT substrate.

The CLK pad and the CKB pad are pads for testing all test time sequence/clock signal leads on the TFT substrate.

### Embodiment I

As shown in FIG. 2, this embodiment discloses a TFT array substrate, including: a substrate 11, provided with a display area AA and a peripheral area DA of the display area; a visual test area 21 (as shown by the elliptical dotted box in FIG. 2), formed in the peripheral area DA and including multiple visual test pads 31, between which gaps 41 with gap directions G1 are formed; and an alignment film (not shown in FIG. 2), formed in the display area AA and having an alignment direction R.

The visual test pads 31 are parallelograms with the same size, center points of all the visual test pads 31 are located on the same straight line, namely all the visual test pads 31 are arranged in parallel along the same straight line, and the visual test pads 31 are arranged at equal intervals. Accordingly, the gaps 41 formed between all the visual test pads 31 are identical in area and interval. Moreover, because the visual test pads 31 are arranged in parallel along the same straight line, the gap directions G1 of the gaps 41 formed between all the visual test pads 31 are identical, as shown in FIG. 2.

Further referring to FIG. 2, each gap direction G1 is staggered with the alignment direction R on the same plane with a staggered angle Θ1, and the staggered angle Θ1 is more than 5 degrees. During a Rubbing process, a lint roller sweeps the gaps 41 formed between the visual test pads 31; and when the staggered angle of each gap direction G1 and the alignment direction R on the same plane is more than 5 degrees, lint on the lint roller does not have a deformation in accordance with the gap direction G1, so that the shape of the originally deployed fine grooves is still kept in the lint, and great difference between the alignment directions of the part of the lint which swept the gaps 41 and those of the other parts is avoided, thus Rubbing uniformity is ensured and obvious Rubbing Mura is avoided.

According to the above-mentioned analysis, the staggered angles of the gap directions G1 and the alignment direction R are the bigger the better within a certain range, namely the bigger the staggered angles are, the lower the influence of the gaps 41 on the Rubbing process is.

In addition, it is worth mentioning that the staggered angles of the gap directions G1 and the alignment direction R on the same plane in the present invention refer to acute staggered angles produced when the gap directions and the alignment direction are staggered; the size of the staggered angles also refers to the size of the acute staggered angles, the staggered angles Θ1 in the present invention are more than 5 degrees, and because the staggered angles are the acute staggered angles, the upper limit of the staggered angles Θ1 is 90 degrees.

In addition, further referring to FIG. 2, the visual test pads 31 in the visual test area 21, according to different test item and function of each visual test pad 31, may include Data R pad, Data G pad, Data B pad, COM pad, Gate Odd pad, Gate Even pad, Switch pad, STV pad, CLK pad or CKB pad. Certainly, the visual test pads in the visual test area 21 are not limited to the aforementioned pads, and may be designed with different test functions according to different functions of the TFT substrate.

Although the geometrical shapes of the visual test pads 31 in the embodiment I of the present invention are parallelograms designed in consideration of the space utilization rate of the visual test area, the geometrical shapes of the visual test pads are not limited to this and generally may be circles, triangles, quadrangles, pentagons, hexagons, heptagons or octagons. The visual test pads which are space-saving and high in geometrical shape symmetry may be designed in consideration of saving the arrangement space.

### Embodiment II

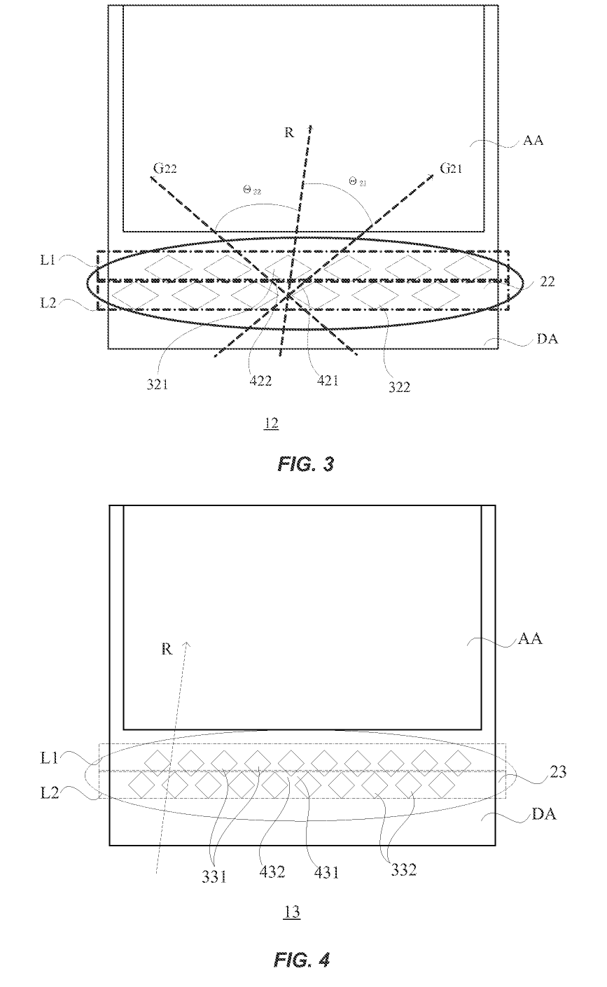

Based on the embodiment I, as shown in FIG. 3, this embodiment discloses a TFT array substrate, including: a substrate 12, provided with a display area AA and a peripheral area DA of the display area; a visual test area 22 (as shown by the elliptical dotted box in FIG. 3), formed in the peripheral area DA; and an alignment film (not shown in FIG. 3), formed in the display area AA and having an alignment direction R.

Referring to FIG. 3, the visual test area 22 includes multiple visual test pads staggered in two parallel lines, namely a first line L1 (as shown by the rectangular dotted box in FIG. 3) and a second line L2 (as shown by the rectangular dotted box in FIG. 3). The visual test pads in the first line L1 are first-line visual test pads 321; and the visual test pads in the second line L2 are second-line visual test pads 322. Wherein, the first-line visual test pads 321 and the second-line visual test pads 322 are of rhombuses with the same size, and the visual test pads in the same line are arranged at equal intervals.

Further referring to FIG. 3, the first-line visual test pads 321 and the second-line visual test pads 322 are integrally parallel to each other, and are alternated and staggered with each other. When the visual test pads are alternated and staggered with each other in two or more lines, gaps formed between the adjacent visual test pads of the same line and between the adjacent visual test pads of different lines are relatively small and are staggered with the alignment direction on the same plane, thus ensuring small influence on the alignment direction in the Rubbing process.

Further referring to FIG. 3, because the visual test pads are arranged in two parallel lines, at least two gaps are formed between each visual test pad and the adjacent visual test pads in the first-line visual test pads 321 and the second-line visual test pads 322, as shown in FIG. 3, taking one of the first-line visual test pads 321 as an example, at least two gaps, namely a gap 421 and a gap 422, are formed between the visual test pad and another visual test pad of the same line and between the visual test pad and one second-line visual test pad 322 of the second line L2. Wherein, the gap 421 has a gap direction G21, and the gap 422 has a gap direction G22.

Further referring to FIG. 3, the gap direction G21 is staggered with the alignment direction R on the same plane with a staggered angle Θ21, and the staggered angle Θ21 is more than 5 degrees; and the gap direction G22 is staggered with the alignment direction R on the same plane with a staggered angle Θ22, and the staggered angle Θ22 is more than 5 degrees. During the Rubbing process, the lint roller sweeps the gap 421 and the gap 422; and when the staggered angle between each of the gap direction G21 and the gap direction G22 and the alignment direction R on the same plane is more than 5 degrees, the lint on the lint roller does not have a deformation in accordance with the gap direction G1, so the shape of the originally deployed fine grooves is still kept in the lint, and great difference between the alignment directions of the part of the lint which swept the gap 421 and the gap 422 and those of the other parts is avoided, thus Rubbing uniformity is ensured and obvious Rubbing Mura is avoided.

In addition, because the first-line visual test pads 321 and the second-line visual test pads 322 are alternated and staggered with each other in two parallel lines, the gaps formed between the visual test pads may be reduced, the arrangement space may be saved, and the space utilization rate of the visual test area is high. Due to the relatively small gaps formed by staggered arrangement of the visual test pads, deformation of the lint on the lint roller in the Rubbing process may be greatly reduced, inconsistency between the alignment directions at the gaps in the presence of the gaps and the other parts is avoided, and the alignment direction of the alignment film is consistent.

In addition, further referring to FIG. 3, the first-line visual test pads 321 and the second-line visual test pads 322 in the visual test area 22, according to different test item and function of each visual test pad, may include Data R pad, Data G pad, Data B pad, COM pad, Gate Odd pad, Gate Even pad, Switch pad, STV pad, CLK pad or CKB pad. Certainly, the visual test pads in the visual test area 22 are not limited to the aforementioned pads, and may be designed with different test functions according to different functions of the TFT substrate.

### Embodiment III

Based on the embodiment II, as shown in FIG. 4, this embodiment discloses a TFT array substrate, including: a substrate 13, provided with a display area AA and a peripheral area DA of the display area; a visual test area 23 (as shown by the elliptical dotted box in FIG. 4), formed in the peripheral area DA; and an alignment film (not shown in FIG. 4), formed in the display area AA and having an alignment direction R.

This embodiment is based on the technical solution of the embodiment II, and the same part between this embodiment and the embodiment II will be omitted herein.

The difference between this embodiment and the embodiment II is as follows.

Referring to FIG. 4, the visual test area 23 includes multiple visual test pads staggered in two parallel lines, namely a first line L1 (as shown by the rectangular dotted box in FIG. 4) and a second line L2 (as shown by the rectangular dotted box in FIG. 4). The visual test pads in the first line L1 are first-line visual test pads 331; and the visual test pads in the second line L2 are second-line visual test pads 332. Wherein, the first-line visual test pads 331 and the second-line visual test pads 332 are of squares with the same size, and the visual test pads in the same line are arranged at equal intervals.

Further referring to FIG. 4, because the visual test pads are arranged in two parallel lines, at least two gaps are formed between each visual test pad and the adjacent visual test pads in the first-line visual test pads 331 and the second-line visual test pads 332, as shown in FIG. 4, taking one of the first-line visual test pads 331 as an example, at least two gaps, namely a gap 431 and a gap 432, are formed between the visual test pad and another visual test pad of the same line and between the visual test pad and one second-line visual test pad 332 of the second line L2.

The visual test pads are designed as the squares with the same size, since the squares have good symmetry, more arrangement space of the visual test area may be saved when the visual test pads are arranged in the visual test area, and it is a good solution for realizing a narrow frame. More importantly, due to the perfect symmetry of the squares, the area of each gap formed between the visual test pads is quite small, the deformation of the lint on the lint roller in the Rubbing process is quite low, and the Rubbing uniformity is substantially not affected, thus the alignment uniformity is ensured.

Generally, the visual test pads are of parallelograms, rhombuses or squares with the same size, and the visual test pads of the same line are arranged at equal intervals. Preferably, the visual test pads are of rhombuses and squares, and the two geometrical shapes have good symmetry, so more arrangement space may be saved when the visual test pads are arranged.

Although the geometrical shapes of the visual test pads in the embodiment II and the embodiment III of the present invention are rhombuses and squares designed in consideration of the space utilization rate of the visual test area, the geometrical shapes of the visual test pads are not limited to this and generally may be circles, triangles, quadrangles, pentagons, hexagons, heptagons or octagons.

### Embodiment IV

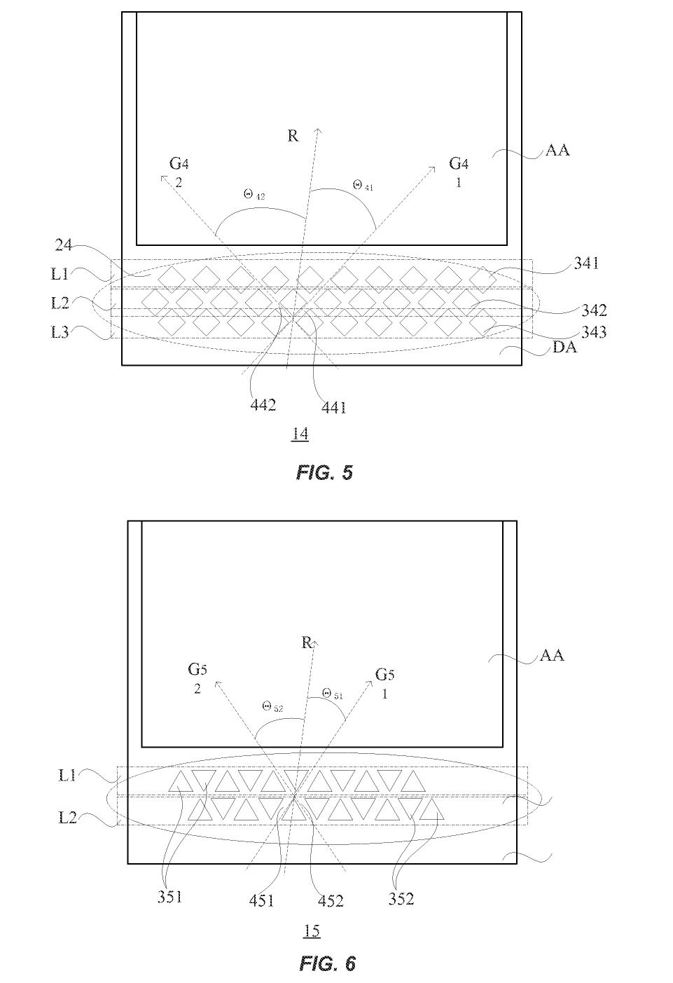

Based on the embodiment II and the embodiment III, as shown in FIG. 5, this embodiment discloses a TFT array substrate, including: a substrate 14, provided with a display area AA and a peripheral area DA of the display area; a visual test area 24 (as shown by the elliptical dotted box in FIG. 5), formed in the peripheral area DA; and an alignment film (not shown in FIG. 5), formed in the display area AA and having an alignment direction R.

This embodiment is based on the technical solutions of the embodiments II and III, and the same part between this embodiment and the embodiments II and III will be omitted herein.

The difference between this embodiment and the embodiments II and III is as follows.

Referring to FIG. 5, the visual test area 24 includes multiple visual test pads staggered in three parallel lines, namely a first line L1 (as shown by the rectangular dotted box in FIG. 5), a second line L2 (as shown by the rectangular dotted box in FIG. 5) and a third line L3 (as shown by the rectangular dotted box in FIG. 5). The visual test pads in the first line L1 are first-line visual test pads 341; the visual test pads in the second line L2 are second-line visual test pads 342; and the visual test pads in the third line L3 are third-line visual test pads 343. Wherein, the first-line visual test pads 341, the second-line visual test pads 342 and the third-line visual test pads 343 are of squares with the same size, and the visual test pads in the same line are arranged at equal intervals.

The visual test pads are designed as the squares with the same size and arranged in three parallel lines, since the squares have good symmetry, and more arrangement space of the visual test area may be saved when the visual test pads are arranged in the visual test area. Meanwhile, because the visual test pads are arranged in three lines, the visual test pads are arranged more tightly, and gaps formed between the visual test pads are smaller and have lower influence on the Rubbing process.

Further referring to FIG. 5, because the visual test pads are arranged in three parallel lines, at least two gaps are formed between each visual test pad and the adjacent visual test pads in the first-line visual test pads 341, the second-line visual test pads 342 and the third-line visual test pads 343. As shown in FIG. 5, taking one of the second-line visual test pads 342 as an example, at least two gaps, namely a gap 441 and a gap 442, are formed between the visual test pad and another visual test pad of the same line, between the visual test pad and one first-line visual test pad 341 of the first line L1 and between the visual test pad and one third-line visual test pad 343 of the third line L3. Wherein, the gap 441 has a gap direction G41, and the gap 442 has a gap direction G42.

Further referring to FIG. 5, the gap direction G41 is staggered with the alignment direction R on the same plane with a staggered angle Θ41, and the staggered angle Θ41 is more than 5 degrees; and the gap direction G42 is staggered with the alignment direction R on the same plane with a staggered angle Θ42, and the staggered angle Θ42 is more than 5 degrees. During the Rubbing process, the lint roller sweeps the gap 441 and the gap 442; and when the staggered angle between each of the gap direction G41 and the gap direction G42 and the alignment direction R on the same plane is more than 5 degrees, the lint on the lint roller does not have a deformation in accordance with the gap direction G1, so that the shape of the originally deployed fine grooves is still kept in the lint, and great difference between the alignment directions of the part of the lint which swept the gap 441 and the gap 442 and those of the other parts is avoided, thus Rubbing uniformity is ensured and obvious Rubbing Mura is avoided.

Although the visual test pads in the embodiment IV of the present invention are designed to be arranged in three parallel lines at equal intervals in consideration of reduction of the gaps between the visual test pads and space utilization rate of the visual test area, the arrangement mode of the visual test pads is not limited to this. Generally, the arrangement mode of the visual test pads, whether the visual test pads need to be arranged at equal intervals, the geometrical shapes of the visual test pads and the like may be designed in consideration of the area of the visual test area of the TFT substrate, items to be tested and other factors.

### Embodiment V

Based on the embodiment II and the embodiment III, as shown in FIG. 6, this embodiment discloses a TFT array substrate, including: a substrate 15, provided with a display area AA and a peripheral area DA of the display area; a visual test area 25 (as shown by the elliptical dotted box in FIG. 6), formed in the peripheral area DA; and an alignment film (not shown in FIG. 6, formed in the display area AA and having an alignment direction R.

This embodiment is based on the technical solutions of the embodiments II and III, and the same part between this embodiment and the embodiments II and III will be omitted herein.

The difference between this embodiment and the embodiments II and III is as follows.

Referring to FIG. 6, the visual test area 25 includes multiple visual test pads staggered in two parallel lines, namely a first line L1 (as shown by the rectangular dotted box in FIG. 6) and a second line L2 (as shown by the rectangular dotted box in FIG. 6). The visual test pads in the first line L1 are first-line visual test pads 351; and the visual test pads in the second line L2 are second-line visual test pads 352. Wherein, the first-line visual test pads 351 and the second-line visual test pads 352 are of equilateral triangles with the same size, and the visual test pads in the same line are arranged at equal intervals.

In addition, in the mutual arrangement mode of one visual test pad 351 (352) of the equilateral triangle and the adjacent visual test pads, at least two gaps, namely a gap 451 and a gap 452, are formed. Wherein, the gap 451 has a gap direction G51, and the gap 452 has a gap direction G52.

Further referring to FIG. 6, the gap direction G51 is staggered with the alignment direction R on the same plane with a staggered angle Θ51, and the staggered angle Θ51 is more than 5 degrees; and the gap direction G52 is staggered with the alignment direction R on the same plane with a staggered angle Θ52, and the staggered angle Θ52 is more than 5 degrees.

The visual test pads are designed as the equilateral triangles with the same size, since the equilateral triangles have good symmetry, more arrangement space of the visual test area may be saved when the visual test pads are arranged in the visual test area, and it is a good solution for realizing a narrow frame. In such design, the area of each gap formed between the visual test pads is quite small, and the influence on Rubbing uniformity is low.

### Embodiment VI

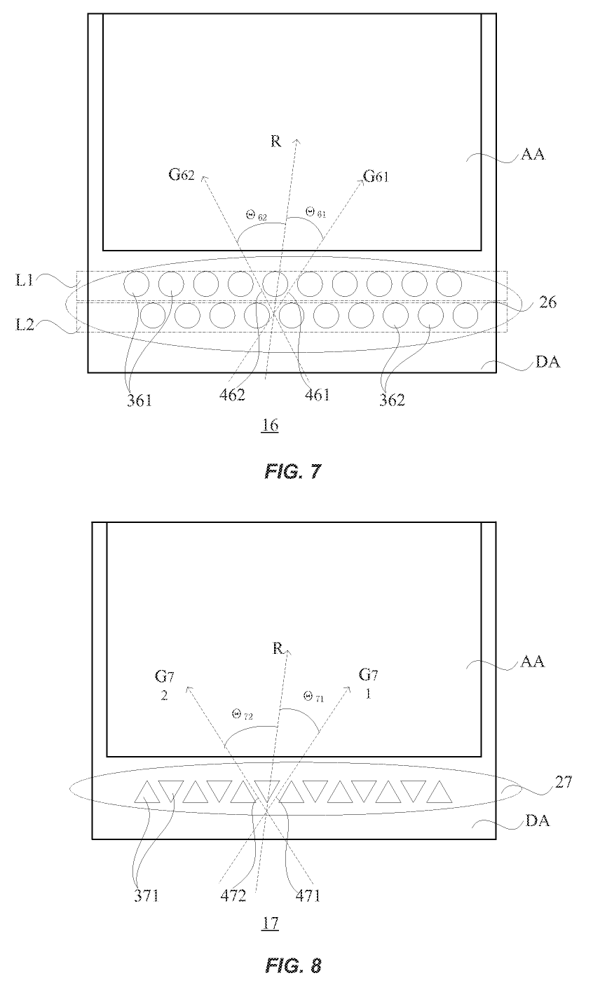

Based on the embodiments II, III and V, as shown in FIG. 7, this embodiment discloses a TFT array substrate, including: a substrate 16, provided with a display area AA and a peripheral area DA of the display area; a visual test area 26 (as shown by the elliptical dotted box in FIG. 7), formed in the peripheral area DA; and an alignment film (not shown in FIG. 7), formed in the display area AA and having an alignment direction R.

This embodiment is based on the technical solutions of the embodiments II, III and V, and the same part between this embodiment and the embodiments II, III and V will be omitted herein.

The difference between this embodiment and the embodiments II, III and V is as follows.

Referring to FIG. 7, the visual test area 26 includes multiple visual test pads staggered in two parallel lines, namely a first line L1 (as shown by the rectangular dotted box in FIG. 7) and a second line L2 (as shown by the rectangular dotted box in FIG. 7). The visual test pads in the first line L1 are first-line visual test pads 361; and the visual test pads in the second line L2 are second-line visual test pads 362. Wherein, the first-line visual test pads 361 and the second-line visual test pads 362 are of circles with the same size, and the visual test pads in the same line are arranged at equal intervals.

In addition, in the mutual arrangement mode of one visual test pad 361 (362) of the circle and the adjacent visual test pads, at least two gaps, namely a gap 461 and a gap 462, are formed. Wherein, the gap 461 has a gap direction G61, and the gap 462 has a gap direction G62.

Further referring to FIG. 7, the gap direction G61 is staggered with the alignment direction R on the same plane with a staggered angle Θ61, and the staggered angle Θ61 is more than 5 degrees; and the gap direction G62 is staggered with the alignment direction R on the same plane with a staggered angle Θ62, and the staggered angle Θ62 is more than 5 degrees.

The visual test pads are designed as the circles with the same size, so that the visual test pads of the circles are easy to implement in the process of preparing the visual test pads, and the process flow is simple.

### Embodiment VII

Based on the embodiments I and V, as shown in FIG. 8, this embodiment discloses a TFT array substrate, including: a substrate 17, provided with a display area AA and a peripheral area DA of the display area; a visual test area 27 (as shown by the elliptical dotted box in FIG. 8), formed in the peripheral area DA; and an alignment film (not shown in FIG. 8), formed in the display area AA and having an alignment direction R.

This embodiment is based on the technical solutions of the embodiments I and V, and the same part between this embodiment and the embodiments I and V will be omitted herein.

The difference between this embodiment and the embodiments I and V is as follows.

Referring to FIG. 8, the visual test area 27 includes multiple visual test pads 371 arranged in one line, and the visual test pads 371 are arranged at equal intervals and are of equilateral triangles with the same size.

In addition, in the mutual arrangement mode of one visual test pad 371 of the equilateral triangle and the adjacent visual test pads, at least two gaps, namely a gap 471 and a gap 472, are formed. Wherein, the gap 471 has a gap direction G71, and the gap 472 has a gap direction G72.

Further referring to FIG. 8, the gap direction G71 is staggered with the alignment direction R on the same plane with a staggered angle Θ71, and the staggered angle Θ71 is more than 5 degrees; and the gap direction G72 is staggered with the alignment direction R on the same plane with a staggered angle Θ72, and the staggered angle Θ72 is more than 5 degrees.

The visual test pads 371 are designed as the equilateral triangles, since the equilateral triangles have good symmetry, more arrangement space of the visual test area may be saved when the visual test pads are arranged in the visual test area.

Each part in the specification is described in a progressive mode, what is highlighted in each part is difference from other parts, and for the same or similar parts between all the parts, reference could be made to each other.

For the above-mentioned illustration of the disclosed embodiments, those skilled in the art may realize or use the present invention. Multiple modifications of these embodiments are obvious for those skilled in the art, and general principles defined herein may be realized in other embodiments without departing from the spirit or scope of the present invention. Accordingly, the present invention will not be limited to the embodiments shown herein, but accords with the widest scope consistent with the principles and novel characteristics disclosed herein.

What is claimed is:

1. A TFT array substrate, comprising: a substrate, provided with a display area and a peripheral area of the display area;
a visual test area, formed in the peripheral area and comprising at least two visual test pads between which at least one gap with a gap direction is formed; and
an alignment film, formed in the display area and having an alignment direction;
wherein, the gap direction is staggered with the alignment direction on the same plane with at least one staggered angle; and
the staggered angle is more than 5 degrees.

2. The TFT array substrate of claim 1, wherein the visual test pads are arranged in an alternated and staggered mode.

3. The TFT array substrate of claim 2, wherein geometric shapes of the visual test pads are circles, triangles, quadrangles, pentagons, hexagons, heptagons or octagons.

4. The TFT array substrate of claim 3, wherein the quadrangles are parallelograms, rhombuses or squares.

5. The TFT array substrate of claim 1, wherein the visual test pads are arranged in at least two lines, namely first-line visual test pads and second-line visual test pads which are arranged in an alternated and staggered mode.

6. The TFT array substrate of claim 5, wherein the visual test pads are identical in geometric shape and size.

7. The TFT array substrate of claim 1, wherein the visual test pads are arranged in at least three lines, namely first-line visual test pads, second-line visual test pads and third-line visual test pads which are arranged in an alternated and staggered mode.

8. The TFT array substrate of claim 7, wherein the visual test pads are identical in geometric shape and size.

9. The TFT array substrate of claim 1, wherein the visual test area at least comprises a Data R pad, a Data G pad, a Data B pad, a COM pad, a Switch pad, a Gate Odd pad or a Gate Even pad.

10. The TFT array substrate of claim 9, wherein the visual test area further comprises a STV pad, a CLK pad or a CKB pad.

11. A display panel comprising a TFT array substrate, a color filter substrate opposite to the TFT array substrate and a liquid crystal layer between the TFT array substrate and the color filter substrate, wherein the TFT array substrate comprises: a substrate, provided with a display area and a peripheral area of the display area;
a visual test area, formed in the peripheral area and comprising at least two visual test pads between which at least one gap with a gap direction is formed; and
an alignment film, formed in the display area and having an alignment direction;
wherein, the gap direction is staggered with the alignment direction on the same plane with at least one staggered angle; and
the staggered angle is more than 5 degrees.

12. The display panel of claim 11, wherein the visual test pads are arranged in an alternated and staggered mode.

13. The display panel of claim 12, wherein geometric shapes of the visual test pads are circles, triangles, quadrangles, pentagons, hexagons, heptagons or octagons.

14. The display panel of claim 13, wherein the quadrangles are parallelograms, rhombuses or squares.

15. The display panel of claim 11, wherein the visual test pads are arranged in at least two lines, namely first-line visual test pads and second-line visual test pads which are arranged in an alternated and staggered mode.

16. The display panel of claim 15, wherein the visual test pads are identical in geometric shape and size.

17. The display panel of claim 11, wherein the visual test pads are arranged in at least three lines, namely first-line visual test pads, second-line visual test pads and third-line visual test pads which are arranged in an alternated and staggered mode.

18. The display panel of claim 11, wherein the visual test area at least comprises a Data R pad, a Data G pad, a Data B pad, a COM pad, a Switch pad, a Gate Odd pad or a Gate Even pad.

19. The display panel of claim 18, wherein the visual test area further comprises a STV pad, a CLK pad or a CKB pad.

20. A display device comprising the display panel of claim 11.
